(19) United States
(12) Patent Application Publication
(10) Pub. No.: US 2018/0112019 A1
(43) Pub. Date: Apr. 26, 2018

(54) LIGHT EMITTER DEVICES AND COMPONENTS WITH IMPROVED CHEMICAL RESISTANCE AND RELATED METHODS

(71) Applicant: HONEYWELL INTERNATIONAL INC., MORRIS PLAINS, NJ (US)

(72) Inventors: Ya Qun Lin, Shanghai (CN); Wanchao Jiang, Shanghai (CN); Gang Xu, Shanghai (CN); Linlin Duan, Shanghai (CN); Siyuan Zhang, Shanghai (CN); Zhe Ding, Shanghai (CN)

(21) Appl. No.: 15/585,766

(22) Filed: May 3, 2017

Related U.S. Application Data
(63) Continuation-in-part of application No. 15/353,676, filed on Nov. 16, 2016.
Application No. 15/353,676 is a continuation-in-part of application No. 15/477,645, filed on Apr. 3, 2017.
Application No. 15/477,645 is a continuation of application No. 14/463,747, filed on Aug. 20, 2014, now Pat. No. 9,624,325.
(60) Provisional application No. 62/331,080, filed on May 3, 2016.
(60) Provisional application No. 62/257,875, filed on Nov. 20, 2015.
(60) Provisional application No. 61/894,146, filed on Oct. 22, 2013.

(51) Int. Cl. C08F 214/18; C09D 127/12

(52) U.S. Cl. CPC C08F 214/188; C08F 214/186; C08F 214/18; C09D 127/12

(57) ABSTRACT

Disclosed are LEDs and LED packages, and methods of making them, having improved resistance to infiltration by chemical entities comprising providing a coating on at least a portion of the LED chip or an LED chip package formed by co-polymerization of:
(a) one or more hydrofluoroolefin monomer(s) selected from the group consisting of tetrafluoroethylene, hydrofluoroethylenes, hydrofluoropropenes, hydrofluorobutenes, hydrofluoropentenes and combinations of these;
(b) optionally one or more chlorofluoroethylene monomers;
(c) optionally one or more vinyl ester monomer(s); and
(d) optionally one or more vinyl ether monomer(s), wherein at least a portion of said vinyl ether monomer is preferably a hydroxyl group-containing vinyl ether monomer and preferably at least one of (b) and (d) is present.

### CROSS REFERENCE TO RELATED APPLICATIONS

The present application claims the priority benefit of U.S. Provisional Application 62/331,080, filed on May 3, 2016, which is incorporated herein by reference.

The present application claims the priority benefit of as a Continuation-In-Part of U.S. application Ser. No. 15/353,676, filed on Nov. 16, 2016, now pending, which in turn claims the priority of U.S. Provisional 62/257,875, each of which is incorporated herein by reference.

The present application continuation-in-part and claims the priority benefit of U.S. application Ser. No. 15/477,645, filed on Apr. 3, 2017, now pending, which is incorporated herein by reference.

### FIELD OF THE INVENTION

This invention relates generally to light emitter devices, components and methods with improved resistance to chemicals and/or chemical vapors or gases that can have an adverse effect the brightness and reliability of such devices.

### BACKGROUND

Light emitting diodes (LEDs) or LED chips are light sources that operate by using compound semiconductor material such as GaAs, AlGaAs, GaN, InGaN, AlGaInP and the like. The LED has the advantage of emitting various colors depending the on materials of the semiconductor and are developing as replacements for incandescent, fluorescent, and metal halide high-intensity discharge (HID) light products.

Two types of LED packages are commonly used-lamp type LEDs and surface mounted LEDs (referred to sometimes as SMDs). For a typical lamp type LED package, designated as 10 in FIG. 1A, a metal electrode face of a cup shape with a predetermined angle is provided on the upper side of a lead frame 3B among two lead frames 3A, 3B. An LED device 5 is mounted on the upper side of the metal electrode face. Also, the lamp type LED 10 is packaged by a domed case 7 which is typically made of transparent molding resin. The domed case 7 operates as a lens and helps to control the luminance of the device.

A surface mounted type LED package, designated as 20 in FIG. 1B, typically has a package 11 which can be made of molding epoxy resin and/or ceramic layers and an LED device 15 arranged on a mounting region and wires 13 connecting the LED to electrodes 16. In the surface mounted type LED package 20, the luminance and the distribution of the luminance are largely impacted by the package construction. In typical configurations, the body 11 can include or have attached thereto a structure which forms a cavity formed by the inclined side 26A, such as would be formed by a frusto-conically shaped cavity, and the LED is mounted to a portion of the body within the cavity. In typical arrangements, the cavity is filled with an encapsulant 28. Silicones are frequently used for the encapsulant due in large part to its high optical transparency, favorable mechanical properties and superior thermal and radiation stability.

Although the encapsulant provides some protection to the components contained within the cavity, applicants have come to appreciate that many of the components that form part of the LED package, such as metallic traces, electrodes, electrically conductive mounting surfaces and the like can become tarnished, corroded, or otherwise degraded during use and/or the manufacturing process notwithstanding the presence of the encapsulant. Applicants have come to appreciate that under varied and common circumstances certain materials can penetrate from the environment into the package and have a deleterious effect on such component. Applicants have also come to appreciate that under other varied and common circumstances the encapsulant itself and or other components of the package many have residues and/or may include other components which migrate to and/or form at the interface with the package and cause problems with adhesion of the encapsulant to the package, which in turn can make the package more susceptible to attack and deterioration as a result of penetration of gases or other materials in the environment.

For example, certain chemicals and/or chemical vapors present in the environment and/or present in components of the package can enter and/or permeate through conventional light emitter devices, for example, by permeating an encapsulant filling material disposed over such components or through other cracks or fissures in the package. Sulfur and sulfur containing chemicals are such chemicals, and the process of sulfidation (also referred to as sulfuration) is relevant in this regard. Sulfur is known to be present in gaskets, adhesives, tailpipe emissions and other common materials. Sulfidation involves the corrosion of metal (e.g., silver, copper, etc.) in the presence of sulfur compounds in a liquid or gaseous phase, particularly in the presence of elevated levels of moisture. Sulfidation is frequently initiated through the reduction of H₂S or COS to HS⁻ or S²⁻, which in turn can then either react directly with silver ions or copper ions from the package that have oxidized, or they can absorb to the surface, subsequently reacting to form the sulfide salt. The presence of an oxidizing species, such as Cl, has been shown to increase the corrosion rate. The principal product of the reaction of HS⁻ or S²⁻ and silver is silver sulfide (Ag₂S). This process over time can discolor the silver-based layers and coatings in LED packages, particularly SMDs, which can in turn have the effect of reducing the light output of the LED and/or causing other deleterious effects. Such reactions can also cause other problems, such as deterioration or failure of electrical connections or the thin metal wires used to make the connections.

Thus, applicants have come to appreciate that LED products made and used before the present invention were generally susceptible to degradation due to the presence of undesirable chemicals and/or chemical vapors in the environments of use, including by way of example sulfur, sulfur-containing compounds (e.g., sulfides, sulfites, sulfates, SOx), chlorine and bromine containing compounds and complexes, nitric oxide or nitrogen dioxides (e.g., NOx), and oxidizing organic vapor compounds. These and other materials can permeate the encapsulant (or through other cracks or fissures in the package) and physically degrade various components within the light emitter device via corroding, oxidizing, darkening, and/or tarnishing such components. Such degradation can adversely affect brightness, reliability, and/or thermal properties of conventional light emitter devices over time, and can further adversely affect the performance of the devices during operation.

Applicants have come to recognize that this potential problem with existing LED designs is becoming more acute as such components are used more frequently in a wide variety of applications that expose the package to more extreme conditions and environments. For example, LEDs are being used increasingly in lighting systems in the automotive, boating and recreational vehicle industry, and in these uses are exposed to higher stress conditions, such as vibration, variations in temperature, humidity and others. Due to the proximity of various components and materials in such applications, the environment in these applications can present an increased source of such degrative chemicals and vapors. Furthermore, at higher temperatures such degrative substances can enter the environment from materials like foam pads, rubber sealing, anti-vibration pads, thermal conductive pads and others. These substances may not only get into contact with the surface of the LED but can also diffuse through the silicone encapsulation and could finally contaminate the die, bond wire and leadframe. Such materials can also be found in the manufacturing environment for the LED package.

Applicants have thus come to appreciate a need devices and components having improved chemical resistance and related methods for preventing undesirable chemicals and/or chemical vapors from reaching and subsequently degrading components within the devices. Devices, components, and methods described herein can advantageously improve chemical resistance to undesirable chemicals and/or chemical vapors within encapsulated light emitter devices, while promoting ease of manufacture and increasing device reliability, especially in high power and/or high brightness applications and/or in environments with extreme conditions of temperature, humidity, vibration and the like.

### SUMMARY

One aspect of the present invention provides methods of forming LEDs and LED packages with improved resistance to infiltration by chemical entities comprising:

(a) providing at least a portion of an LED chip or an LED chip package;

(b) providing a coating composition comprising:
(1) one or more fluoroolefin monomer(s), preferably selected from the group consisting of tetrafluoroethylene, hydrofluoroethylenes, hydrofluoropropenes, hydrofluorobutenes, hydrofluoropentenes and combinations of these, and preferably selected from tetrafluoroethylene, 2,3,3,3-tetrafluoropropene, 1,3,3,3-tetrafluoropropene, with said 1,3,3,3-tetrafluoropropene preferably comprising, consisting essentially of or consisting of trans-1,3,3,3-tetrafluoropropene, and combinations of these;
(2) optionally but preferably one or more chlorofluoroethylene monomers, preferably chlorotrifluoroethylene (“CTFE”) monomers;
(3) optionally but preferably one or more vinyl ester monomer(s); and
(4) optionally one or more vinyl ether monomer(s), wherein at least a portion of said vinyl ether monomer is a hydroxyl group-containing vinyl ether monomer.

(c) coating at least a portion of said at least a portion of an LED chip or an LED chip package or a component thereof with said provided coating, preferably by a wet process; and

(d) curing said coating to provide a protective coating on said at least a portion of an LED chip or an LED chip package or a component thereof.

Another aspect of the present invention provides LEDs and LED packages with improved resistance to infiltration by chemical entities comprising:

(a) an LED chip or an LED chip package;

(b) a protective coating on at least a portion or component of said LED chip or an LED chip package, said coating comprising a cofluoropolymer, a terfluorocopolymer, and preferably a tetrafluorcopolymer, formed by copolymerization of:
(1) one or more fluoroolefin monomer(s), preferably selected from the group consisting of tetrafluoroethylene, hydrofluoroethylenes, hydrofluoropropenes, hydrofluorobutenes, hydrofluoropentenes and combinations of these, and preferably selected from t2,3,3,3-tetrafluoropropene, 1,3,3,3-tetrafluoropropene, with said 1,3,3,3-tetrafluoropropene preferably comprising, consisting essentially of or consisting of trans-1,3,3,3-tetrafluoropropene, and combinations of these;
(2) optionally but preferably one or more chlorofluoroethylene monomers, preferably chlorotrifluoroethylene (“CTFE”) monomers;
(3) optionally but preferably one or more vinyl ester monomer(s); and
(4) optionally but preferably one or more vinyl ether monomer(s), wherein at least a portion of said vinyl ether monomer is a hydroxyl group-containing vinyl ether monomer,
   provided at least one of monomers (2) or (4) are included.

Another aspect of the present invention provides LEDs and LED packages with improved resistance to infiltration by chemical entities comprising:

(a) an LED chip or an LED chip package;

(b) a protective coating on at least a portion or component of said LED chip or an LED chip package, said coating comprising:
(1) a cofluoropolymer, a terfluorocopolymer, and preferably a terfluorocopolymer, said copolymer formed by copolymerization of:
   (a) one or more fluoroolefin monomer(s), preferably selected from the group consisting of tetrafluoroethylene, hydrofluoroethylenes, hydrofluoropropenes, hydrofluorobutenes, hydrofluoropentenes, chlorofluoroethylene, preferably chlorotrifluoroethylene (“CTFE”), and combinations of these, and preferably selected from tetrafluoroethylene, 2,3,3,3-tetrafluoropropene, 1,3,3,3-tetrafluoropropene, and CTFE, with said 1,3,3,3-tetrafluoropropene when present preferably comprising, consisting essentially of or consisting of trans-1,3,3,3-tetrafluoropropene, and combinations of these;
   (b) optionally, but preferably present, one or more vinyl ester monomer(s); and
   (c) optionally but preferably present, one or more vinyl ether monomer(s), wherein at least a portion of said vinyl ether monomer is a hydroxyl group-containing vinyl ether monomer,
(2) curing agent, preferably an isocyanate or amine; and
(3) solvent for (1) and (2), preferably butyl acetate or xylene.

Another aspect of the present invention provides method of producing LEDs and LED packages with improved resistance to infiltration by chemical entities comprising:

(a) providing an LED chip or an LED chip package;

(b) providing on at least a portion or surface of said LED chip or LED chip package a protective coating on at least a portion or component of said LED chip or an LED chip package, said coating comprising:
(1) a cofluoropolymer, a terfluorocopolymer, a tetrafluorocopolymer and preferably a terfluorocopolymer, said copolymer formed by copolymerization of:
   (i) one or more fluoroolefin monomer(s), preferably selected from the group consisting of tetrafluoroethylene, hydrofluoroethylenes, hydrofluoropropenes, hydrofluorobutenes, hydrofluoropentenes, chlorofluoroethylene, preferably chlorotrifluoroethylene (“CTFE”), and combinations of these, and preferably selected from tetrafluoroethylene, 2,3,3,3-tetrafluoropropene, 1,3,3,3-tetrafluoropropene, and CTFE, with said 1,3,3,3-tetrafluoropropene when present preferably comprising, consisting essentially of or consisting of trans-1,3,3,3-tetrafluoropropene, and combinations of these;
   (ii) optionally, but preferably present, one or more vinyl ester monomer(s); and
   (iii) optionally but preferably present, one or more vinyl ether monomer(s), wherein at least a portion of said vinyl ether monomer is a hydroxyl group-containing vinyl ether monomer,
(2) curing agent, preferably an isocyanate or amine; and
(3) solvent for (1) and (2), preferably butyl acetate or xylene; and

(c) crosslinking at least a portion of said coating composition, preferably by exposing, after said coating step, said coating composition to heat for a time effective to crosslink at least a portion of said coating composition.

### BRIEF DESCRIPTION OF THE DRAWINGS

FIG. 1A is a schematic depiction of a lamp-type of light emitter device.

FIG. 2 is a schematic depiction of a surface mount-type of light emitter device.

FIG. 3A is a schematic illustration of a first embodiment of a light emitter device in accordance with a partial state of assembly according to the disclosure herein.

FIG. 3B is a schematic illustration of a first embodiment of a light emitter device in accordance with a partial state of assembly according to the disclosure herein.

FIG. 3C is a schematic illustration of a first embodiment of a light emitter device in accordance with a partial state of assembly according to the disclosure herein.

FIG. 3D is a schematic illustration of a second embodiment of a light emitter device in accordance with a partial state of assembly according to the disclosure herein.

FIG. 3E is a schematic illustration of a third embodiment of a light emitter device in accordance with a partial state of assembly according to the disclosure herein.

FIG. 3F is a schematic illustration of a third embodiment of a light emitter device in accordance with a partial state of assembly according to the disclosure herein.

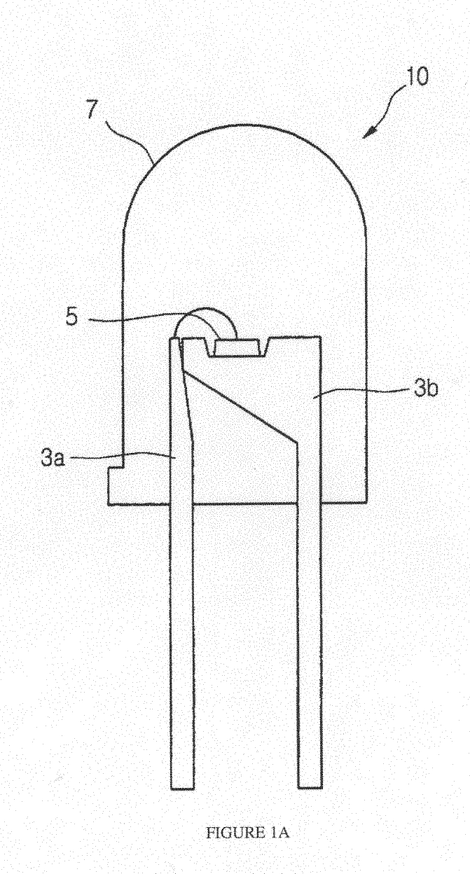

### DETAILED DESCRIPTION

The Methods

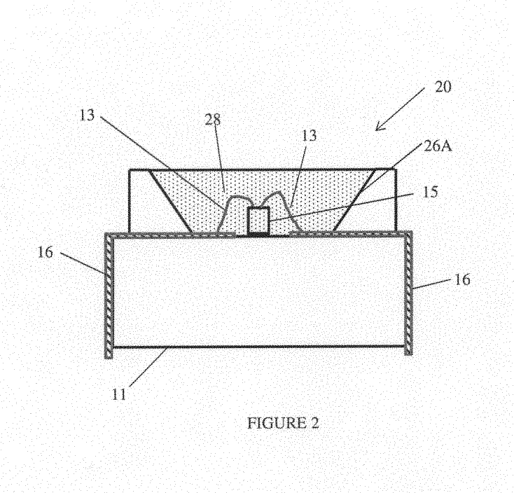

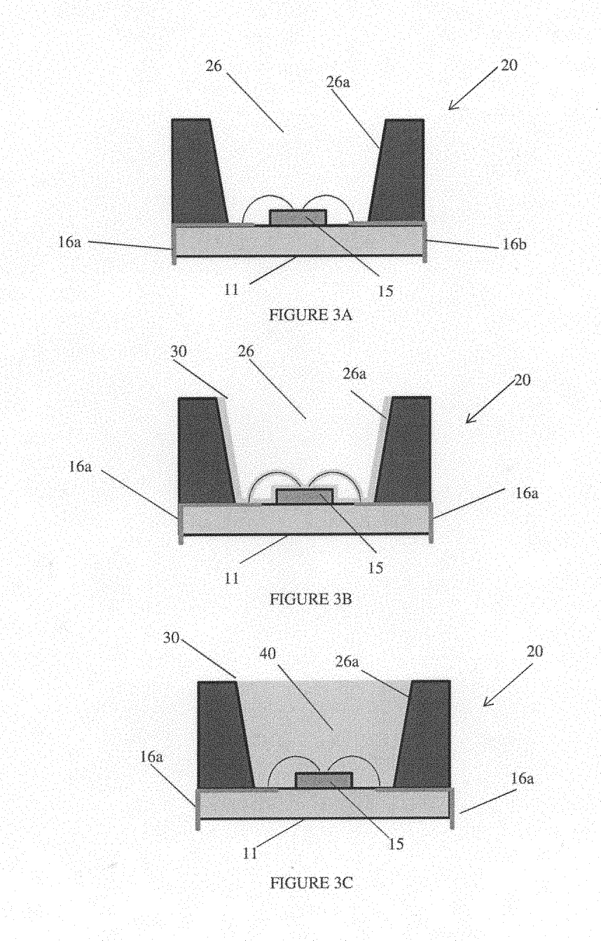

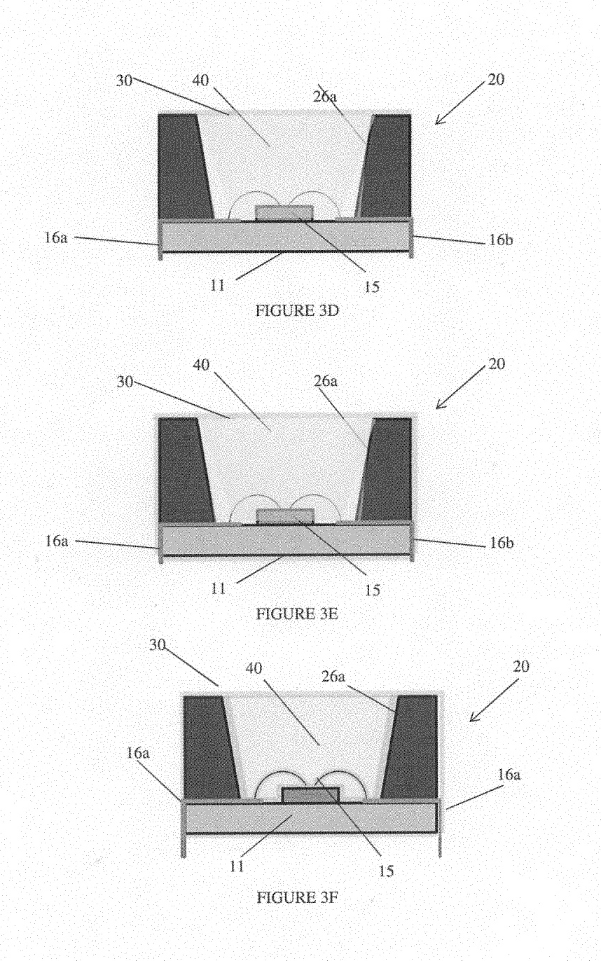

A first group of preferred embodiments of the method aspects of present invention is explained herein in connection with FIGS. 3A-3C. FIG. 3A illustrates in schematic view a light emitter device, designated generally as 20, in a state of assembly prior to completion. In the illustrated state of completion, which is achieved by methods well known in the art, the package includes a body 11, which is disposed about a leadframe containing a central thermal element (not shown) and one or more electrical elements 16a and 16b. In a typical embodiment, body 11 comprises a plastic body molded about the leads, and the light emitter device comprises a surface mount device (SMD) comprising a body 15 which can be molded or otherwise formed about one or more electrical leads 16a or 16b. The LED chip 15 electrically communicates with one and/or both first and second electrical elements 16a and 16b via one or more electrical connectors such as electrically conductive wire bonds 13. It will be appreciated that the LED chip 15 having two electrical contacts on the same side (e.g., upper surface) are shown and being connected by wire bonds is exemplary only and that other configurations are possible. For example, LED chip 15 can comprise a horizontally structured chip (e.g., having at least two electrical contacts on a same side of the LED) or a vertically structured chip (e.g., with electrical contacts on opposing sides of the LED). In preferred embodiments, the body 11 comprises a cavity, generally designated 26, having sides 26a, which in many preferred embodiments are coated with a reflective material for reflecting light from the LED chip 15.

Preferred embodiments of the present methods include applying a protective coating composition on one or more of the surfaces of the components of the LED package, and even more preferably one or more metallic components of the LED package located within the cavity in which the LED chip is mounted. In certain preferred embodiments, the step of applying the protective coating of the present invention occurs before and/or after the cavity is filled with encapsulant, but preferably at least before the cavity is filled with encapsulant. In highly preferred embodiments, the step of applying the protective coating of the present invention results in substantially all surfaces of the components located in the cavity, as well as the sides of the cavity itself, being coated with the present protective coating, to provide a coating layer 30, as is illustrated schematically in FIG. 3B.

One advantage of the coating step of the present invention, and of the coating composition of the present invention, is that the step of applying can be carried out in a wet coating process, and even more preferably the step of applying the protective coating can use the same equipment, or at least a substantial portion of the same equipment, used to deposit the encapsulant into the cavity. As those skilled in the art will appreciate, such preferred methods provide substantial advantages over other types of deposition processes that may have been used to apply protective films to electronic components, such as vapor deposition and electroplating. Applicants believe that the coating composition of the present invention, as described in more detail hereinafter, not only provide superior performance once the coating is formed, the use of such coating compositions according to the present methods provides significant and unexpected advantages in terms of the speed and/or cost of manufacture and assembly process.

The methods of the present invention preferably comprise applying a liquid coating composition to the substrate or surface to be protected. For the purposes of convenience, this process is sometimes referred to as a wet coating process and is intended to include methods comprising the application of a liquid film, layer or spray to a substrate and forming a protective film or coating from said liquid, including wet solution-based casting methods. In some preferred embodiments, the wet coating process includes spray coating, spin coating, dip coating, knife coating, blade coating, brush coating, curtain coating and combinations of these. In other of preferred embodiments, the wet coating process includes dispense dropping, inkjeting, or printing method.

Once the coating composition of the present invention is applied, it is preferably cured in situ to produce a coating which will resist, to a much greater degree than the encapsulant, passage of chemical entities, include those potentially harmful chemical entities described above, and thereby protect the coated components of the LED package. The preferred curing processes of the present invention comprise drying of the wet/liquid coating to form a cured protective layer or film. In some preferred embodiments, the curing process includes solvent removal of the coating. In some preferred embodiments, the curing process includes solvent removal and chemical reaction, such as the crosslinking of the chemical bonds. In some preferred embodiments, the curing process includes air evaporating/drying or thermal baking. In some preferred embodiments, the temperature of the curing process is about 25 degree to about 200 degree centigrade. In some preferred embodiment, the curing process will take several minutes to several days. The thickness of the cured coating layer according to preferred embodiments of the present invention is at least 1 nm. It will be appreciated by those skilled in the art that the thickness of the cured coating layer will in many embodiments depend on the structure of the LED chip or LED chip packages. In some preferred embodiments, the thickness of cured coating layer 30, as illustrated schematically in FIG. 3B, is from about 5 nm to 500 nm. In some preferred embodiments, thickness of cured coating layer 30, as illustrated schematically in FIG. 3D, is about 5 nm to 5 mm. Once the coating layer of the present invention is cured, the preferred embodiments of the present invention include the further step of filling the cavity which contains the LED chip with encapsulant (shown as 40 in FIG. 3C) according to materials and procedures well known in the art.

### The LED

As will be appreciated by those skilled in the art, the present methods can be used to form a wide variety of LEDs and packages which contain LEDs having superior performance relative to those previously made. All such types and classes of LEDs and LED packages are within the scope of the present invention, provided they incorporate a layer of protective coating using the composition and/or the methods disclosed herein. It is also contemplated that the specific coating layer can be present on one or more components of the LED or the LED package. As mentioned above, in preferred embodiments the coating of the present invention is present on substantially all of the components and devices within the cavity of a surface mount device which contains the LED chip. Reference will now be made in detail to possible aspects or embodiments of the subject matter herein, one or more examples of which are shown in the figures. Each example is provided to explain the subject matter and not necessarily as a limitation. In fact, features illustrated or described as part of one embodiment can be used in another embodiment to yield still a further embodiment. It is intended that the subject matter disclosed and envisioned herein covers such modifications and variations.

As illustrated in the various figures, some sizes of structures or portions are exaggerated relative to other structures or portions for illustrative purposes and, thus, are provided to illustrate the general structures of the present subject matter. Furthermore, various aspects of the present subject matter are described with reference to a structure or a portion being formed on other structures, portions, or both. As will be appreciated by those of skill in the art, references to a structure being formed “on” or “above” another structure or portion contemplates that additional structure, portion, or both may intervene. References to a structure or a portion being formed “on” another structure or portion without an intervening structure or portion are described herein as being formed “directly on” the structure or portion. Similarly, it will be understood that when an element is referred to as being “connected”, “attached”, or “coupled” to another element, it can be directly connected, attached, or coupled to the other element, or intervening elements may be present. In contrast, when an element is referred to as being “directly connected”, “directly attached”, or “directly coupled” to another element, no intervening elements are present.

Furthermore, relative terms such as “on”, “above”, “upper”, “top”, “lower”, or “bottom” are used herein to describe one structure's or portion's relationship to another structure or portion as illustrated in the figures. It will be understood that relative terms such as “on”, “above”, “upper”, “top”, “lower” or “bottom” are intended to encompass different orientations of the device in addition to the orientation depicted in the figures. For example, if the device in the figures is turned over, structure or portion described as “above” other structures or portions would now be oriented “below” the other structures or portions.

The present LEDs and LED packages thus provide devices and components having improved chemical resistance to undesirable chemicals and/or chemical vapors from reaching and subsequently degrading components within the devices. Devices, components, and methods described herein can advantageously improve chemical resistance to undesirable chemicals and/or chemical vapors within encapsulated light emitter devices, while promoting ease of manufacture and increasing device reliability and performance in high power and/or high brightness applications. The described devices and/or methods can be used and applied to create chemically resistant surface mount device (SMD) type of light emitter devices of any size, thickness, and/or dimension. Devices, components, and methods described herein can advantageously be used and adapted within any style of light emitter device, for example, devices including a single LED chip, multiple LED chips, and/or multi-arrays of LED chips and/or devices incorporating different materials for the body or submount such as plastic, ceramic, glass, aluminum nitride (AlN), aluminum oxide (Al2O3), printed circuit board (PCB), metal core printed circuit board (MCPCB), and aluminum panel based devices. Notably, devices, components, and methods herein can prevent degradation of optical and/or thermal properties of devices or packages incorporating silver (Ag) components and/or Ag-plated components by preventing tarnishing of the Ag or Ag-plated components.

Light emitting diodes (LEDs) or LED chips according to embodiments described herein can comprise group III-V nitride (e.g., gallium nitride (GaN)) based LED chips or lasers that can be fabricated on a growth substrate, for example, a silicon carbide (SiC) substrate, such as those devices. Other growth substrates are also contemplated herein, for example and not limited to sapphire, silicon (Si) and GaN. In one aspect, SiC substrates/layers can be 4H polytype silicon carbide substrates/layers. Other SiC candidate polytypes, such as 3C, 6H, and 15R polytypes, however, can be used. The methods for producing such substrates are set forth in the scientific literature as well as in a number of U.S. patents, including but not limited to U.S. Pat. No. Re. 34,861; U.S. Pat. No. 4,946,547; and U.S. Pat. No. 5,200,022, the disclosures of each of which are incorporated by reference herein in their entireties. Any other suitable growth substrates are contemplated herein.

As used herein, the term “Group III nitride” refers to those semiconducting compounds formed between nitrogen and one or more elements in Group III of the periodic table, usually aluminum (Al), gallium (Ga), and indium (In). The term also refers to binary, ternary, and quaternary compounds such as GaN, AlGaN and AlInGaN. The Group III elements can combine with nitrogen to form binary (e.g., GaN), ternary (e.g., AlGaN), and quaternary (e.g., AlInGaN) compounds. These compounds may have empirical formulas in which one mole of nitrogen is combined with a total of one mole of the Group III elements. Accordingly, formulas such as AlxGa1-xN where 1>x>0 are often used to describe these compounds. Techniques for epitaxial growth of Group III nitrides have become reasonably well developed and reported in the appropriate scientific literature.

Both vertical and horizontal LED chip structures can be formed using the present methods and/or using the present coating layer, and such structures are discussed by way of example in U.S. Publication No. 2008/0258130 to Bergmann et al. and in U.S. Publication No. 2006/0186418 to Edmond et al., the disclosures of each of which are hereby incorporated by reference herein in their entireties.

### The Coating and Coating Composition

According to one aspect of the present invention the protective coating hereof comprises, and preferably consists essentially of or consists of a fluorocopolymer as formed by copolymerization of:
(1) one or more fluoroolefin monomer(s), preferably selected from the group consisting of tetrafluorethylene, hydrofluoroethylenes, hydrofluoropropenes, hydrofluorobutenes, hydrofluoropentenes and combinations of these, and preferably selected from 2,3,3,3-tetrafluoropropene, 1,3,3,3-tetrafluoropropene, with said 1,3,3,3-tetrafluoropropene preferably comprising, consisting essentially of or consisting of trans-1,3,3,3-tetrafluoropropene, and combinations of these, and
(2) optionally one or more chlorofluoroethylene monomers, preferably chlorotrifluoroethylene (“CTFE”) monomers, wherein the mole ratio of monomer (1) to monomer (2) is preferably from about 30:1 to about 1:30.

As used herein, the term he term “copolymer” means polymers having two or more different repeating units, and the term “fluorocopolymer” means copolymers in which at least one of the repeating units is based on a monomer that is a fluoroolefin, preferably tetrafluorethylene and/or a hydrofluoroolefin. The term “terpolymer” means polymers having three or more different repeating units, and the term “terfluorocopolymer” means terpolymers in which at least one of the repeating units is based on a monomer that is a fluoroolefin, preferably tetrafluorethylene and/or a hydrofluoroolefin. The term “tetrapolymer” is intended to include oligomers and copolymers having four or more different repeating units, and the term “tetrafluorocopolymer” means tetrapolymers in which at least one of the repeating units is based on a monomer that is a fluoroolefin, preferably tetrafluorethylene and/or a hydrofluoroolefin. Thus, a tetrapolymer derived from monomers A, B, C and D has repeating units (-A-), (-B-), (-C-) and (-D-), and a tetrafluorocopolymer derived from monomers A, B, C and D wherein at least one of these is a fluoroolefin, preferably tetrafluorethylene and/or a hydrofluoroolefin.

The repeating units according to the present invention can be arranged in any form, including as alternating copolymers, as periodic copolymers, statistical copolymers, block copolymers and graft copolymers.

According to certain preferred embodiments, the present invention provides terfluorocopolymers, and preferably tetrafluorcopolymers, formed by copolymerization of:
(1) one or more fluoroolefins, preferably tetrafluorethylene and/or a hydrofluoroolefin monomer(s) selected from the group consisting of hydrofluoroethylenes, hydrofluoropropenes, hydrofluorobutenes, hydrofluoropentenes and combinations of these, and preferably selected from 2,3,3,3-tetrafluoropropene, 1,3,3,3-tetrafluoropropene, with said 1,3,3,3-tetrafluoropropene preferably comprising, consisting essentially of or consisting of trans-1,3,3,3-tetrafluoropropene, and combinations of these;
(2) optionally one or more chlorofluoroethylene monomers, preferable chlorotrifluoroethylene (“CTFE”) monomers;
(3) optionally but preferably one or more vinyl ester monomer(s); and
(4) optionally but preferably one or more vinyl ether monomer(s), wherein at least a portion of said vinyl ether monomer is a hydroxyl group-containing vinyl ether monomer.

In preferred embodiments, the protective coating of the present invention is formed by methods comprising the steps of:

(a) providing a coating composition formed by steps comprising:
(i) providing one or more fluoropolymers by copolymerization of (1) one or more fluoroolefins (preferably in certain embodiments hydrofluoroolefin monomer(s), preferably selected from the group consisting of tetrafluoroethylene, hydrofluoroethylenes, hydrofluoropropenes, hydrofluorobutenes, hydrofluoropentenes and combinations of these, and preferably selected from 2,3,3,3-tetrafluoropropene, 1,3,3,3-tetrafluoropropene, with said 1,3,3,3-tetrafluoropropene preferably comprising, consisting essentially of or consisting of trans-1,3,3,3-tetrafluoropropene, and combinations of these, (2) one or more chlorofluoroethylene monomers, preferably chlorotrifluoroethylene (“CTFE”) monomers, (3) one or more vinyl ester monomer(s), and (4) one or more vinyl ether monomer(s), wherein at least a portion of said vinyl ether monomer is a hydroxyl group-containing vinyl ether monomer, wherein the copolymer preferably has a number average molecular weight of greater than about 10,000, preferably greater than about 12,000 and certain other embodiments greater than about 15,000, as measured according the procedure as described herein; and
(ii) providing a carrier for said one or more fluoropolymers; and (iii) combining said one or more fluoropolymers with said carrier, optionally with further additives, such as curing agent, anti-oxidant and/or leveling agent, to produce a polymeric composition comprising less than about 99.99% by weight of said carrier, preferably with a solids content of about 0.01% to about 50% by weight;

(c) coating at least a portion of the LED and/or the LED package or any component thereof with said coating composition; and

(d) forming a protective polymeric layer on said LED and/or the LED package or any component thereof by allowing at least a substantial portion of said carrier to evaporate into the earth's atmosphere, whereby said protective coating is formed.

According to certain preferred embodiments, the present invention provides coating compositions comprising:
(a) terfluorocopolymers formed by copolymerization of:
   (1) one or more fluoroolefins, preferably tetrafluorethylene, CTFE, hydrofluoropropenes, and combinations of these, and preferably selected from tetrafluorethylene, CTFE, 2,3,3,3-tetrafluoropropene, 1,3,3,3-tetrafluoropropene, with said 1,3,3,3-tetrafluoropropene preferably comprising, consisting essentially of or consisting of trans-1,3,3,3-tetrafluoropropene, and combinations of these;
   (2) at least one vinyl ester monomer(s); and
   (3) at least one vinyl ether monomer(s), wherein at least a portion of said vinyl ether monomer is a hydroxyl group-containing vinyl ether monomer,
(b) curing agent, preferably an isocyanate or amine; and
(c) solvent for (a) and (b), preferably butyl acetate or xylene.

In preferred embodiments, the protective coating of the present invention is formed by methods comprising the steps of:
(a) providing a coating composition formed by steps comprising:
   (i) providing one or more fluoropolymers by copolymerization of (1) one or more fluoroolefins (preferably in certain embodiments hydrofluoroolefin monomer(s), preferably selected from the group consisting of tetrafluoroethylene, CTFE, hydrofluoroethylenes, hydrofluoropropenes, hydrofluorobutenes, hydrofluoropentenes and combinations of these, and preferably selected from tetrafluoroethylene, CTFE, 2,3,3,3-tetrafluoropropene, 1,3,3,3-tetrafluoropropene, with said 1,3,3,3-tetrafluoropropene when present preferably comprising, consisting essentially of or consisting of trans-1,3,3,3-tetrafluoropropene, and combinations of these, (2) one or more vinyl ester monomer(s), and (3) one or more vinyl ether monomer(s), wherein at least a portion of said vinyl ether monomer is a hydroxyl group-containing vinyl ether monomer, preferably according to any one of the embodiments described herein, wherein the copolymer preferably has a number average molecular weight of greater than about 8,000 to about 20,000, preferably greater from about 10,000 to about 15,000, as measured according the procedure as described herein; and
   (ii) providing curing agent for said one or more fluoropolymers (i), preferably an isocyanate or amine curing agent; and
   (iii) providing a carrier for said one or more fluoropolymers and said curing agent; and
(b) combining said one or more fluoropolymers with said curing agent and said carrier, optionally with further additives, such as anti-oxidant and/or leveling agent, to produce a polymeric composition comprising less than about 99.99% by weight of said carrier, preferably with a solids content of about 0.01% to about 50% by weight;
(c) coating at least a portion of the LED and/or the LED package or any component thereof with said coating composition; and
(d) forming a protective polymeric layer on said LED and/or the LED package or any component thereof by removing at least a substantial portion of said carrier and by crosslinking using said crosslinking agent, said evaporating and said crosslinking preferably comprising heating said coating after said step (c).

In preferred embodiments, the protective coating of the present invention is formed by methods comprising the steps of:

(a) providing a coating composition formed by steps comprising:
(i) providing one or more fluoropolymers by copolymerization of, preferably solution polymerization, of:
   (1) from about 40 mol % to about 60 mol %, and even more preferably from about 45 mol % to about 55 mol %, and even more preferably about 50 mol % of fluoroolefin monomers (preferably in certain embodiments hydrofluoroolefin monomer(s), preferably selected from the group consisting of tetrafluoroethylene, CTFE, hydrofluoroethylenes, hydrofluoropropenes, hydrofluorobutenes, hydrofluoropentenes and combinations of these, and preferably selected from tetrafluoroethylene, CTFE, 2,3,3,3-tetrafluoropropene, 1,3,3,3-tetrafluoropropene, with said 1,3,3,3-tetrafluoropropene when present preferably comprising, consisting essentially of or consisting of trans-1,3,3,3-tetrafluoropropene, and combinations of these;
   (2) from about 5 mol % to about 45 mol % of vinyl ester or vinyl ether or both of them, preferably vinyl ester and vinyl ether, more preferably from about 10 mol % to about 40 mol %, and even more preferably from about 20 mol % to about 40 mol %, represented by formula CH₂═CR¹—O(C═O)_{X}R² and CH₂═CR³—OR⁴ respectively, wherein x is 1 and wherein R¹ and R³ are independently either hydrogen or a methyl group, preferably hydrogen, and wherein R² and R⁴ are independently selected from the group consisting of an unsubstituted straight-chain, branched-chain or alicyclic alkyl group having 1 to 12 carbon atoms, preferably from 2 to 8 carbon atoms; and
   (3) from about 3 mol % to about 30 mol % of hydroxyalkyl vinyl ether, more preferably from about 3 mol % to about 20 mol %, and even more preferably from about 3 mol % to about 10 mol % represented by formula CH₂═CR³—O—R⁵—OH, where R³ is as defined above, preferably hydrogen, and R⁵ is selected from the group consisting of an C2 to C12 unsubstituted straight-chain, branched-chain or alicyclic alkyl group, more preferably an unsubstituted straight chain alkyl group having from 3 to 5 carbons, preferably 4 carbons, wherein the mol % are based on the total of the monomers in the copolymer formation step;
(ii) providing curing agent for said one or more fluoropolymers (i), preferably an isocyanate or amine curing agent; and
(iii) providing a carrier for said one or more fluoropolymers and said curing agent; and

(b) combining said one or more fluoropolymers with said curing agent and said carrier, optionally with further additives, such as anti-oxidant and/or leveling agent, to produce a polymeric composition;

(c) coating at least a portion of the LED and/or the LED package or any component thereof with said coating composition; and

(d) forming a protective polymeric layer on said LED and/or the LED package or any component thereof by removing at least a substantial portion of said carrier and by crosslinking using said crosslinking agent, said evaporating and said crosslinking preferably comprising heating said coating after said step (c). In preferred embodiments the one or more fluoropolymers of step (a)(i) are fluoropolymers formed according to the teachings of (a) U.S. application Ser. No. 15/353,676 and/or 9,624,325, each of which is incorporated herein by reference.

In preferred embodiments, the protective coating of the present invention is formed by methods comprising the steps of:

(a) providing a coating composition formed by steps comprising:
(i) providing one or more fluoropolymers by copolymerization of, preferably solution polymerization, of:
   (1) from about 40 mol % to about 60 mol %, and even more preferably from about 45 mol % to about 55 mol %, and even more preferably about 50 mol % of trans-1,3,3,3-tetrafluoropropene;
   (2a) from about 5 mol % to about 45 mol % of vinyl ester, more preferably from about 10 mol % to about 40 mol %, and even more preferably from about 10 mol % to about 20 mol %, represented by formula CH₂═CR¹—O(C═O)_{X}R², wherein x is 1 and wherein R¹ is either hydrogen or a methyl group, preferably hydrogen, and wherein R² is selected from the group consisting of an unsubstituted straight-chain, branched-chain or alicyclic alkyl group having 1 to 12 carbon atoms, preferably from 2 to 8 carbon atoms; and
   (2b) from about 5 mol % to about 45 mol % of vinyl ether, more preferably from about 10 mol % to about 40 mol %, and even more preferably from about 10 mol % to about 20 mol %, represented by formula CH₂═CR³—OR⁴ respectively, wherein R³ is either hydrogen or a methyl group, preferably hydrogen, and wherein R⁴ is selected from the group consisting of an unsubstituted straight-chain, branched-chain or alicyclic alkyl group having 1 to 12 carbon atoms, preferably from 2 to 8 carbon atoms; and
   (3) from about 3 mol % to about 30 mol % of hydroxyalkyl vinyl ether, more preferably from about 3 mol % to about 20 mol %, and even more preferably from about 3 mol % to about 10 mol % represented by formula CH₂═CR³—O—R⁵—OH, where R³ is as defined above, preferably hydrogen, and R⁵ is selected from the group consisting of an C2 to C12 unsubstituted straight-chain, branched-chain or alicyclic alkyl group, more preferably an unsubstituted straight chain alkyl group having from 3 to 5 carbons, preferably 4 carbons, wherein the mol % are based on the total of the monomers in the copolymer formation step;
(ii) providing curing agent for said one or more fluoropolymers (i), preferably an isocyanate or amine curing agent; and
(iii) providing a carrier for said one or more fluoropolymers and said curing agent; and

(b) combining said one or more fluoropolymers with said curing agent and said carrier, optionally with further additives, such as anti-oxidant and/or leveling agent, to produce a polymeric composition;

(c) coating at least a portion of the LED and/or the LED package or any component thereof with said coating composition; and

(d) forming a protective polymeric layer on said LED and/or the LED package or any component thereof by removing at least a substantial portion of said carrier and by crosslinking using said crosslinking agent, said evaporating and said crosslinking preferably comprising heating said coating after said step (c). In preferred embodiments the one or more fluoropolymers of step (a)(i) are fluoropolymers formed according to the teachings of (a) U.S. application Ser. No. 15/353,676 and/or 9,624,325, each of which is incorporated herein.

For embodiments comprising curing agent, it k contemplated that a variety of specific compounds and compositions may be used in view of the teachings contained herein. In preferred embodiments, the curing agents are compounds that are reactive, for example, with hydroxyl groups on the copolymer, Preferred curing agents may be selected from polyisocyanate curing agents and melamine resins. Preferred polyisocyanurates curing agents are aliphatic polyisocyanates, cycloaliphatic polyisocyanates and/or aromatic polyisocyanates, and preferably contain two or more isocyanate groups. Preferred polyisocyanates include, or may be derived from, 1,6-hexamethylene diisocyanates; toluene diisocyanate; 2,2,4-trimethylhexamethylene diisocyanate; 3-isocyanatomethyl-3,5,5-trimethyl-cyclohexyl isocyanate; methylene-bis(4-cyclohexylisocyanate); and 4,4-diphenylmethanediisocyanate. Preferred polyisocyanates comprise the trimer isocyanates, for example those derived from 1,6-hexamethylene diisocyanate, commercially available as Desmodur N from Bayer Corporation (i.e. Desmodur N-3390, having an NCO value of 19.7% according to DIN EN ISO 11909). Preferred melamine resins include alkylated melamine resins, and include, or may be derived from, hexamethoxymethylmelamines. Melamine resins are commercially available under the name Cymel from Cytec in by reference.
According to preferred aspects, the present invention provides tetrafluorocopolymers as described in the previous paragraph wherein the polymer has a number average molecular weight of greater than about 10,000, preferably greater than about 12,000, and preferably in other embodiments greater than about 15,000.

According to certain preferred embodiments, the fluorocopolymer coating composition of the present invention has a solid content of from about about 0.01% to about 50% by weight, and even more preferably in certain embodiments from about 0.1% to about 10% by weight. In preferred embodiments the fluorocopolymer coating composition of this invention has a solid content of from about 0.5% to about 5% by weight.

As used herein, the term fluoroolefin means compounds containing at least carbon and fluorine, including but not limited to consisting of only carbon and fluorine, and at least one carbon-carbon double bond.

As used herein, the term hydrofluoroolefin means compounds consisting of carbon, hydrogen and fluorine and at least one carbon-carbon double bond and includes but is not necessarily limited to hydrofluoroethylene, hydrofluoropropene, hydrofluorobutene and hydrofluoropentene, and the like. According to certain preferred embodiments, the hydrofluoroolefin used to form the coating composition of step (b) comprises 1,3,3,3-tetrafluoroolefin (HFO-1234ze), with said 1,3,3,3-tetrafluoropropene preferably comprising, consisting essentially of or consisting of trans-1,3,3,3-tetrafluoropropene, and/or 2,3,3,3-tetrafluoroolefin (HFO-1234yf).

As used herein, the term chlorofluoroethylene means compounds consisting of 2 carbon atoms having a carbon-carbon double bond, chlorine and fluorine, and includes but is not necessarily limited to chlorotrifluoroethylene.

In preferred embodiments, the protective fluoropolymer coating of the present invention is formed by solution copolymerization of the monomers represented by (1), (2), (3) and (4) of step (a) (i). In preferred embodiments, step (a)(i) comprises solution copolymerizing:

(1) from about 40 mol % to about 60 mol %, and even more preferably from about 45 mol % to about 55 mol %, and even more preferably about 50 mol % of fluoroolefin monomers (preferably hydrofluoroolefin monomer(s)), preferably selected from the group consisting of hydrofluoroethylenes, hydrofluoropropenes, hydrofluorobutenes and hydrofluoropentenes, more preferably from the group consisting of HFO-1234ze, HFO-1234yf and combinations of these, and even more preferably HFO-1234ze, with said HFO-1234ze preferably comprising, consisting essentially of or consisting of trans-HFO-1234ze;

(2) from about 40 mol % to about 60 mol %, and even more preferably from about 45 mol % to about 55 mol %, and even more preferably about 50 mol % of chlorofluoroethylene monomer(s), preferably CTFE, wherein the mole ration of monomer (1) to monomer (2) is preferably from about 30:1 to about 1:30;

(3) from about 5 mol % to 45 mol % of vinyl ester or vinyl either or both of them, more preferably from about 10 mol % to about 40 mol %, and even more preferably from about 20 mol % to about 40 mol %, represented by formula CH₂═CR¹—O(C═O)_{X}R² and CH₂═CR³—OR⁴ respectively, wherein x is 1 and wherein Wand R³ are independently either hydrogen or a methyl group, preferably hydrogen, and wherein R² and R⁴ are independently selected from the group consisting of an unsubstituted straight-chain, branched-chain or alicyclic alkyl group having 1 to 12 carbon atoms, preferably from 2 to 8 carbon atoms; and

(4) from about 3 mol % to about 30 mol % of hydroxyalkyl vinyl ether, more preferably from about 3 mol % to about 20 mol %, and even more preferably from about 3 mol % to about 10 mol % represented by formula CH₂═CR³—O—R⁵—OH, where R³ is as defined above, preferably hydrogen, and R⁵ is selected from the group consisting of an C2 to C12 unsubstituted straight-chain, branched-chain or alicyclic alkyl group, more preferably an unsubstituted straight chain alkyl group having from 3 to 5 carbons, preferably 4 carbons, wherein the mol % are based on the total of the monomers in the copolymer formation step.

According to a preferred embodiment of the present invention, the co-polymer formation step (a) (i) comprises providing one or more fluorocopolymers by copolymerization of:
(1) first monomer(s) consisting essentially of HFO-1234ze, preferably transHFO-1234ze and/or HFO-1234yf, preferably in an amount of from about 5 mol % to about 60 mol %, and more preferably from about 10 mol % to about 55 mol %,
(2) second monomer comprising CTFE, preferably in an amount of from about 5 mol % to about 60 mol %, and more preferably from about 10 mol % to about 55 mol %, wherein the mole ratio of monomer (1) to monomer (2) is from about 5:1 to about 1:5, more preferably from about 2:1 to about 1:2;
(3) third monomer(s) comprising:
   A) vinyl ester monomer(s), preferably in an amount of from about 5 mol % to about 45 mol %, more preferably more preferably from about 10 mol % to about 30 mol %, and even more preferably from about 10 mol % to about 20 mol %, represented by formula CH₂═CR¹—O(C═O)_{X}R², wherein x is 1 and wherein R¹ is either hydrogen or a methyl group, and wherein R² is selected from the group consisting of a substituted or unsubstituted straight-chain or branched-chain alkyl group having 5 to 12 carbon atoms, wherein said alkyl group includes at least one tertiary or quaternary carbon atom, and
   B) vinyl ether monomer(s), preferably in amounts of from about 10 mol % to about 40 mol % of vinyl ether, more preferably from about 5 mol % to about 45 mol %, more preferably form about 10 mol % to about 30 mol %, and even more preferably from about 10 mol % to about 20 mol %, represented by formula CH₂═CR³—OR⁴ respectively, wherein R³ is independently either hydrogen or a methyl group and wherein R⁴ are independently selected from the group consisting of a substituted or unsubstituted straight-chain or branched-chain alkyl group having 1 to 5 carbon atoms; and
   (4) fourth monomer(s) selected from hydroxyl group-containing vinyl ether monomer(s), preferably in an amount of from about 3 mol % to about 60 mol % of hydroxy vinyl ether monomer, preferably in an amount of from about 3 mol % to about 30 mol %, more preferably from about 3 mol % to about 20 mol %, and even more preferably from about 3 mol % to about 10 mol %, represented by formula CH₂═C—R⁵—OH, where R⁵ is selected from the group consisting of an C2 to C6 substituted or unsubstituted straight-chain or branched-chain alkyl group, wherein the mol % are based on the total of the monomers in the copolymer formation step.

As used herein, unless otherwise specifically indicated, reference to mol % is to the mol % of monomers used in the formation of the fluorocopolymer of the present invention, based on the total of the monomers.

In certain preferred embodiments, the copolymer formed by step (a) of the present invention has a number average molecular weight as measured by gel phase chromatography (“GPC”) according to the method described in Skoog, D. A. Principles of Instrumental Analysis, 6th ed.; Thompson Brooks/Cole: Belmont, Calif., 2006, Chapter 28, which is incorporated herein by reference, of from about 3000 to about 50000, or from about 4000 to about 50000, or from about 5000 to about 50000, or from about 12000 to about 20000 and in certain embodiments a weight average molecular weight preferably from about 3000 to about 30,000, or from about 5000 to about 30,000, and more preferably from about 20,000 to about 30,000. Unless specifically indicated to the contrary herein, reference to number average molecular weight means number average molecular weight as measured in accordance with this paragraph.

As used herein, the term “substrate” refers to any part or component, including the entirety of the LED chip, device or package.

As used herein, the term “carrier” is intended to refer to a component of a composition that serves to solvate, disperse and/or emulsify a monomeric or polymeric component of a composition.

As those skilled in the art will appreciate, the quality of a protective coating applied to a substrate can be measured by a variety of coating properties that, depending on the particular application, are important for achieving a commercially successful coating on a given substrate. These properties include but are not limited to: (1) viscosity, (2) color retention and (3) substrate adhesion. According to certain preferred embodiments, the coating compositions formed according to the present methods exhibit: (1) a solid concentration of about 0.01% to 50.00% by weight; (2) a viscosity, as measured by the ASTM Standard Test Method for Measuring Solution Viscosity of Polymers with Differential Viscometer, Designation D5225-14, of not greater than about 1700 at 25° C. and a color change after about 1000 hours, of not greater than 2.0, more preferably not greater than about 1.5, and even more preferably not greater than about 1.2, as measured in comparison to the initial color, each as measured by ASTM D 7251, QUV-A.

In preferred embodiments, the polymers of the present invention have a hydroxyl value of greater than about 70, and in other preferred embodiments have a hydroxyl value of greater than about 90. As mentioned above, the ability to achieve such a method resides, in part, on the judicious selection of the type and the amounts of the various components that are used to form the fluoropolymer and the coating compositions of the present invention.

In preferred embodiments, the polymers of the present invention have a fluorine content of from about 15% to about 20% by weight and a chlorine content of from about 12% to about 18% by weight. In other preferred embodiments, the polymers of the present invention have fluorine content of from about 16% to about 18% by weight and a chlorine content of from about 14% to about 16% by weight.

Monomers

Fluoroolefins

The fluoroolefin monomers of the present invention are selected in preferred embodiments from the group consisting of tetrafluorethylene and hydrofluoroolefin monomers. The hydrofluoroolefin monomers according to the methods of the present invention can include in certain preferred embodiments hydrofluoroethylene monomer, that is, compounds having the formula CX¹X²═CX³X⁴; wherein X′, X², X³, X⁴ are each independently selected from H or F or Cl atom, but at least one of them is a hydrogen atom. Examples of hydrofluoroethylene monomers include, among others:
CH₂═CHF,
CHF═CHF,
CH₂═CF₂, and
CHF═CF₂.

The hydrofluoroolefin monomers according to certain preferred aspects of the methods of the present invention include, and preferably consists essentially of or consist of hydrofluoropropene having the formula CX⁵X⁶═CX⁷CX⁸X⁹X¹⁰; wherein X⁵, X⁶, X⁷, X⁸, X⁹ and X¹⁰ are independently selected from H or F or Cl atom, but at least one of them is a hydrogen atom. Examples of hydrofluoro-propene monomers include, among others:
CH₂═CFCF₃ (HFO-1234yf),
transCHF=CHCF₃ (transHFO-1234ze),
CHCI═CFCF₃ and
CH₂═CHCF₃.

In preferred embodiments, the hydrofluroolefin comprises, consists essentially of or consist of HFO-1234yf and/or HFO-1234ze. In preferred embodiments, the hydrofluroolefin comprises, consists essentially of or consist of HFO-1234ze, with said HFO-1234ze preferably comprising, consisting essentially of or consisting of trans-HFO-1234ze.

The hydrofluoroolefin monomers according to certain preferred aspects of the methods of the present invention include, hydrofluorobutene according to the following formula: CX¹¹X¹²═CX¹³CX¹⁴X¹⁵CX¹⁶X¹⁷X¹⁸; wherein X¹¹, X¹², X¹³, X¹⁴, X¹⁵, X¹⁶. X¹⁷ and X¹⁸ are independently selected from H or F or Cl atom, but at least one of them is a hydrogen atom. Examples of hydrofluorobutene include, among others, CF₃CH═CHCF₃.

Vinyl Esters

The copolymers in accordance with the present invention preferably are also formed from vinyl ester monomer units, preferably in amounts of from about 5 mol % to about 45 mol %, more preferably more preferably from about 10 mol % to about 30 mol %, and even more preferably from about 10 mol % to about 20 mol %. In preferred embodiments the vinyl ester monomer(s) are represented by the formula CH₂═CR¹—O(C═O)_{X}R², wherein x is 1 and wherein R¹ is either hydrogen or a methyl group, and wherein R² is selected from the group consisting of a substituted or unsubstituted, preferably unsubstituted, straight-chain or branched-chain, preferably branched chain, alkyl group having 5 to 12 carbon atoms, more preferably having from 5 to 10 carbon atoms, and even more preferably 8 to 10 carbon atoms. In preferred embodiments the alkyl group includes at least one tertiary or quaternary carbon atom. In highly preferred embodiments, the vinyl ester is compound which includes at least one quaternary carbon according to the following formula:

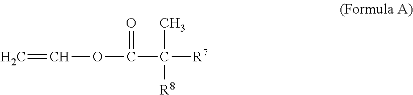

where each of R⁷ and R⁸ are alkyl groups, preferably branched alkyl groups, that together contain from 5 to about 8, more preferably from 6 to 7, carbon atoms.

Examples of vinyl ester monomers that are preferred according to certain preferred embodiments include vinyl acetate, vinyl propionate, vinyl butyrate, vinyl pivalate, vinyl capronate, vinyl laurate, VEOVA-9 (vinyl versatate ester formed from a C9 carbocylic acid, produced by Momentive), VEOVA-10 (vinyl versatate ester formed from a C10 carbocylic acid, produced by Momentive) and vinyl cyclohexanecarboxylate. Each of VEOVA-9 and VEOVA-10 contain at least one quaternary carbon according to Formula A above. According to preferred embodiments the vinyl ester comprises vinyl versatate ester having from 11 to 12 carbon atoms in the molecule, preferably with at least one quaternary carbon according to Formula A above.

Vinyl Ethers

The copolymers in accordance with the present invention preferably are also formed from vinyl ether monomer units, preferably in amounts of from about 5 mol % to about 45 mol %, more preferably more preferably from about 10 mol % to about 30 mol %, and even more preferably from about 10 mol % to about 20 mol %. In preferred embodiments the vinyl ester monomer(s) are represented by the formula CH₂═CR³—OR⁴, wherein R³ is independently either hydrogen or a methyl group and wherein R⁴ is selected from the group consisting of a substituted or unsubstituted, preferably unsubstituted, straight-chain or branched-chain, preferably straight chain, alkyl group having 1 to 5 carbon atoms, more preferably 1 to 3 carbon atoms. Examples of vinyl ether monomers that are preferred according to certain preferred embodiments include alkyl vinyl ethers such as methyl vinyl ether, ethyl, propyl vinyl ether, n-butyl vinyl ether, isobutyl vinyl ether, hexyl vinyl ether, octyl vinyl ether, decyl vinyl ether and lauryl vinyl ether. Vinyl ethers including an alicyclic group can also be used, for example, cyclobutyl vinyl ether, cyclopentyl vinyl ether and cyclohexyl vinyl ether. According to preferred embodiments the vinyl ether comprises, consists essentially of, or consists of ethyl vinyl ether.

Preferably in those embodiments in which vinyl ether and vinyl ester monomers are both present, the amount of vinyl ether and vinyl ester monomers together comprise from about 25 mol % to about 45 mol % of the total monomers.

Hydroxy Vinyl Ethers

The copolymers in accordance with the present invention preferably are also formed from hydroxyl vinyl ether monomer units, preferably in amounts of from about 3 mol % to about 60 mol % of hydroxy vinyl ether monomer, preferably in an amount of from about 3 mol % to about 30 mol %, more preferably from about 3 mol % to about 20 mol %, and even more preferably from about 3 mol % to about 10 mol %. In preferred embodiments the hydroxyl vinyl ether monomer(s) are represented by the formula represented by formula CH₂═CR³—O—R⁵—OH, where R³ is as defined above, preferably hydrogen, and where R⁵ is selected from the group consisting of an C2 to C6 substituted or unsubstituted, preferably unsubstituted, straight-chain or branched-chain, preferably straight chain, alkyl group. Examples of preferred hydroxyalkyl vinyl ether monomers include hydroxyl-ethyl vinyl ether, hydroxypropyl vinyl ether, hydroxybutyl vinyl ether, hydroxypentyl vinyl ether and hydroxyhexyl vinyl ether. In certain embodiments, the copolymer is formed from about 5 mol % to about 20 mol % of hydroxyalkyl vinyl ether monomers, based on the total weight of the monomer.

In preferred embodiments, the comonomers according to the fluorocopolymer formation step (a)(i) comprise, and preferably consist essentially of:

(1) first monomer consisting essentially of HFO-1234ze, preferably in an amount of from about 20 mol % to about 30 mol %, and even more preferably from about 22 mol % to about 27 mol %, and even more preferably about 25 mol %,

(1) second monomer consisting essentially of CTFE, preferably in an amount of from about about 20 mol % to about 30 mol %, and even more preferably from about 22 mol % to about 27 mol %, and even more preferably about 25 mol %,

(3) third monomer(s) comprising:
A) vinyl ester monomer represented by formula CH₂═CR¹—O(C═O)_{X}R² wherein x is 1 and wherein R¹ is either hydrogen or a methyl group, preferably hydrogen, and wherein R² is an unsubstituted branched-chain alkyl group having 6 to 8 carbon atoms, wherein said alkyl group preferably includes at least one tertiary or quaternary carbon atom, wherein said vinyl ester monomer is present in an amount of from about 5 mol % to about 45 mol %, more preferably more preferably from about 10 mol % to about 30 mol %, and even more preferably from about 10 mol % to about 20 mol %; and
B) vinyl ether monomer(s), represented by formula CH2═CR³—OR⁴ respectively, wherein R³ is independently either hydrogen or a methyl group, preferably hydrogen, and wherein R⁴ is selected from the group consisting of a substituted or unsubstituted straight-chain or branched-chain, preferably straight chain, alkyl group having 1 to 3 carbon atoms, preferably 2 carbon atoms, said vinyl ether monomer(s) preferably being present in amounts of from about 10 mol % to about 40 mol %, more preferably from about 5 mol % to about 45 mol %, more preferably form about 10 mol % to about 30 mol %, and even more preferably from about 10 mol % to about 20 mol %; and

(4) fourth monomer(s) consisting of hydroxyalkyl vinyl ether represented by formula CH₂═CR³—O—R⁵—OH, where R³ is methyl or hydrogen, preferably hydrogen, and R⁵ is selected from the group consisting of an C3 to C5, preferably C4, unsubstituted straight-chain alkyl group, wherein the amount of said third monomer is preferably present in an amount of from about 3 mol % to about 30 mol %.

CoPolymer Formation Methods

It will be appreciated by those skilled in the art, based on the teachings contained herein, that copolymers/tercopolymers/tetracopolymers of the present invention may be formed to achieve the preferred characteristics described herein using a variety of techniques, and all such techniques are within the broad scope of the present invention.

In preferred embodiments, the fluorocopolymer is preferably produced in a polymerization system that utilizes a carrier for the monomer/polymer during and/or after formation. According to one preferred embodiment the carrier acts as a solvent and/or dispersant for the monomer and/or polymer, and such operations include dispersion, emulsion and solution polymerization. Examples of carriers in such systems, including preferably solvents for solution polymerization, include: esters, such as methyl acetate, ethyl acetate, propyl acetate and butyl acetate; ketones, such as acetone, methyl ethyl acetone and cyclohexanone; aliphatic hydrocarbons, such as hexane, cyclohexane, octane, nonane, decane, undecane, dodecane and mineral spirits; aromatic hydrocarbons, such as benzene, toluene, xylene, naphthalene, and solvent napthta; alcohols, such as methanol, ethanol, tert-butanol, iso-propanol, ethylene glycol monoalkyl ethers; cyclic ethers, such as tetrahydrofuran, tetrahydropyran, and dioxane; fluorinated solvents, such as HCFC-225 and HCFC-141b; dimethyl sulfoxide; and the mixtures thereof.

It is contemplated that the temperature conditions used in the polymerization process of the present invention can be varied according to the particular equipment and applications involved and all such temperatures are within the scope of the present invention. Preferably, the polymerization is conducted at a temperature in a range of − from about 30° C. to about 150° C., more preferably from about 40° C. to about 100° C., and even more preferably from about 50° C. to about 70° C., depending on factors such as the polymerization initiation source and type of the polymerization medium.

In certain preferred embodiments, it is preferred that the solution polymerization is conducted under conditions under which the total amount of the solvent used in the copolymerization process, based on the weight of the solvent and monomer in the solution, is from about 10 wt % to about 40 wt %, more preferably in amounts of from about 10 wt % to about 30 wt %, and more preferably in certain embodiments in an amount of form about 15% to about 25%. In certain of such embodiments, the solvent used in the solution copolymerization process comprises, preferably consists essentially of, and more preferably in certain embodiments consists of C2-C5 alkyl acetate, and even more preferably butyl acetate.

In preferred embodiments, the copolymer as formed accordance with the preferred methods described herein is prepared by copolymerizing those monomers under conditions effective to achieve a copolymer having a number average molecular weight of 5000 to 50000, or is some embodiments 5000 to 10000 as measured by gel phase chromatography (“GPC”) according to the method described in Skoog, D. A. Principles of Instrumental Analysis, 6th ed.; Thompson Brooks/Cole: Belmont, Calif., 2006, Chapter 28, which is incorporated herein by reference. In certain embodiments, the copolymer has a number average molecular weight that is greater than about 10000, and even more preferably from 10,000 to about 14,000. According to certain preferred embodiments, the copolymer has a molecular weight distribution of 2 to 10, more preferably 2.5 to 8, and most preferably 3 to 6. Applicants have found that in certain embodiments the use of copolymers having a molecular weight less than 5000 produces weatherability and chemical resistance of the protective coating that is less than is desired for some applications and that when the polymers have a molecular weight of more than 50000, coating compositions having viscosities that may negatively impact the spreading or coating properties of the coating compositions and hence difficulties in the coating operations.

In preferred embodiments, the formation of fluorocopolymer coating compositions comprises, and preferably consists essentially of:
(i) providing one or more fluorocopolymers by copolymerization of
   (1) first monomer consisting essentially of HFO-1234ze, with said HFO-1234ze preferably comprising, consisting essentially of or consisting of trans-HFO-1234ze, preferably in an amount of from about 20 mol % to about 30 mol %, and even more preferably from about 22 mol % to about 275 mol %, and even more preferably about 25 mol %,
   (2) second monomer(s) consisting essentially of CTFE, preferably in an amount of from about 20 mol % to about 30 mol %, and even more preferably from about 22 mol % to about 275 mol %, and even more preferably about 25 mol %,
   (3) third monomers comprising:
      A) vinyl ester monomer represented by formula CH₂═CR¹—O(C═O)_{X}R² wherein x is 1 and wherein R¹ is either hydrogen or a methyl group, preferably hydrogen, and wherein R² is an unsubstituted branched-chain alkyl group having 6 to 8 carbon atoms, wherein said alkyl group preferably includes at least one tertiary or quaternary carbon atom, wherein said vinyl ester monomer is present in an amount of from about 5 mol % to about 45 mol %, more preferably more preferably from about 10 mol % to about 30 mol %, and even more preferably from about 10 mol % to about 20 mol %; and
      B) vinyl ether monomer(s), represented by formula CH₂═CR³—O—R⁴, wherein R³ is either hydrogen or a methyl group, preferably hydrogen, and wherein R⁴ is selected from the group consisting of a substituted or unsubstituted straight-chain or branched-chain, preferably straight chain, alkyl group having 1 to 3 carbon atoms, preferably 2 carbon atoms, said vinyl ether monomer(s) preferably being present in amounts of from about 10 mol % to about 40 mol %, more preferably from about 5 mol % to about 45 mol %, more preferably form about 10 mol % to about 30 mol %, and even more preferably from about 10 mol % to about 20 mol %; and
   (4) fourth monomer(s) consisting of hydroxyalkyl vinyl ether represented by the formula CH₂═CR³—O—R⁵—OH, where R³ is methyl or hydrogen, preferably hydrogen, and R⁵ is selected from the group consisting of an C3 to C5, preferably C4, unsubstituted straight-chain alkyl group, wherein the amount of said third monomer is preferably from about 3 mol % to about 30 mol %; and
(ii) providing a carrier for said one or more fluorocopolymers, preferably selected from aromatic hydrocarbons such as xylene and toluene; alcohols such as n-butanol; esters such as butyl acetate; ketones such as methyl isobutyl ketone, and glycol ethers such as ethyl cellusolve, with C2-C5 alkyl acetate being preferred, and even more preferably comprising, consisting essentially of, or consisting of butyl acetate; and
(iii) combining said one or more fluorocopolymers with said carrier, optionally with further additives, such as curing agent, anti-oxidant and/or leveling agent, to produce a polymeric composition comprising less than about 99.99% by weight of said carrier, preferably with a solids content of from about 0.01% to about 50% by weight. According to preferred embodiments, the fluorocopolymer composition of the present invention, and in particular the fluorocopolymer formed as described in the preceeding sentence, has a polymer number average molecular weight as measured by gel phase chromatography (“GPC”) according to the method described in Skoog, D. A. Principles of Instrumental Analysis, 6th ed.; Thompson Brooks/Cole: Belmont, Calif., 2006, Chapter 28, which is incorporated herein by reference, of from about 5000 and 50000, more preferably from about 7000 to about 15000 and has a solids content of from about 0.01% to about 50% by weight, and even more preferably from about 0.1% to about 10% by weight. It is also preferred in such embodiments as described in the present application in general, and in this paragraph as in particular, that the coating compositions of the present invention have a viscosity at 25° C. of less than about 1900 mPa-s, more preferably less than about 1800 mPa-s and even more preferably of less than about 1700 mPa-s as measured by Ford Cup at least at one of 12 revolutions per minutes (r/m), 30 r/m and 60 r/m, and preferably at all three speeds, preferably as measured according to ASTM D1200-10(2014) or ASTM D2196 as appropriate.

Coating Composition Formation Methods

The copolymers as formed in accordance with the procedures described herein may then be used to form various coating compositions that have the substantial advantages described above. For example, various solvents can be used for the preparation of solution-type paints or coatings by adding those solvents to the fluorocopolymer of the present invention formed as described herein. In certain embodiments, preferred solvents for formation of the coating composition include aromatic hydrocarbons such as xylene and toluene; alcohols such as n-butanol; esters such as butyl acetate; ketones such as methyl isobutyl ketone, and glycol ethers such as ethyl cellusolve and various commercial thinners. In some embodiments, the additives, such as curing agent, anti-oxidants and/or leveling agent, are further added to the fluorocopolymer solutions of the present invention.

In certain embodiments, the coating composition of the present invention has a solid content of from about 0.01% to about 50% by weight based on the total weight of the coating composition, and more preferably in certain embodiments from about 0.1% to about 10% by weight of solids. In certain preferred embodiments, the solids comprise and preferably consist essentially of the copolymers of the present invention and/or crosslinked copolymers formed using the copolymers of the present invention.

### EXAMPLES

The present invention is further illustrated by the following non-limiting examples.

### Example 1—Fluoropolymer Preparation

A solution polymerization operation is carried out by charging into a 300 ml stainless steel autoclave equipped with a stirrer the components as indicated in the following Table 1A:

TABLE 1A

| | | | | Mono- | Mono- |
|---|---|---|---|---|---|
| COMPONENT | | Weight, | | mer | mer, |
| TYPE | NAME | grams | Wt % | Moles | mol % |
| Solvent | toluene | 120 | 66 | | |
| First Monomer | trans-1,3,3,3- | 9.24 | 5.1 | 0.17 | 25.32 |
| (fluoropolymer) | tetrafluoro- | | | | |
| | propene | | | | |
| | (transHFO- | | | | |
| | 1234ze) | | | | |
| Second Monomer | CTFE | 9.38 | 5.2 | 0.17 | 25.32 |
| Third Monomer | VEOVA-10 | 23.63 | 13 | 0.12 | 17.58 |
| (vinyl ester) | | | | | |
| Third Monomer | ethyl vinyl | 8.6 | 4.7 | 0.12 | 18.09 |
| (ethyl vinyl ether) | ether | | | | |
| Fourth Monomer | hydroxybutyl- | 10.83 | 6 | 0.19 | 13.75 |
| (alkylhydroxy | vinyl ether | | | | |
| ether) | | | | | |
| Initiator | tertbutyl- | 0.2 | 0.1 | | |
| | peroxypivalate | | | | |

The toluene, the ethyl vinyl ether monomer, the vinyl ester monomer (VEOVA-10), the hydroxybutyl vinyl ether, the initiator and 0.8 grams of zinc oxide were charged into the vessel. The mixture was solidified with liquid nitrogen, and deaerated to remove the dissolved air. Then the trans1,3,3,3-tetrafluoropropene (transHFO-1234ze) and CTFE was added to the mixture in the autoclave, and the mixture was then gradually heated to about 75° C. The mixture was then stirred for about 4 hours to carry-out solution copolymerization of the monomers. After the autoclave was cooled to room temperature, any unreacted monomers were purged and then the autoclave was opened and a vacuum was applied to the autoclave for a sufficient period of time to remove sufficient excess solvent to achieve a solid content (copolymer content) in the autoclave of about 50-80% by weight. The final fluorocopolymer (without solvent) was tested and found to have: a number average molecular weight (Mn) of about 13600 and a Mw/Mn of 2.3; a hydroxyl value of 96 mg KOH/g; a Fluorine content of 17.5% and a Chlorine content of 14.4%. The resulting copolymer plus solvent combination was in the form of a clear solution having a solid, that is, copolymer, content of about 70%.

The solvent/polymer resulting from the operation described about is then added to each of the materials identified in Table 1B below on a 1:1 weight basis and is found to form a clear solution at room temperature:

TABLE 1B
(a) - Solubility Test (1:1 wt ratio)

| Solvent | Appearance |
|---|---|
| Methanol | Clear solution |
| Ethanol | Clear solution |
| Petroleum Ether | Clear solution |
| n-Hexane | Clear solution |
| Xylene | Clear solution |
| Toluene | Clear solution |
| Methyl Ethyl Ketone | Clear solution |
| Acetone | Clear solution |
| Propylene Glycol | Clear solution |
| Monomethyl Ether | |
| [symbol] | |
| Butyl Acetate | Clear solution |
| THE | Clear solution |

[symbol]

indicates data missing or illegible when filed

The result reported above indicates that the fluorocopolymer according to the present invention is capable of forming solutions with many materials that may be used in or form a substantial part of formulations for protective coatings, and accordingly the present fluorocopolymer has excellent usefulness in the formation of protective coatings in conjunction with a wide variety of materials that may be used, for example, as supplemental carriers in such coating compositions.

### Example 2—Coating Composition and Coating Properties

A coating composition in the form of a white paste is formed by adding butyl acetate as thinner into copolymer solution formed in Example 1 to obtain a solution with a solid content of about 30-40 wt %. This solution is then charged into a glass flask and agitated at 250 rpm. A vacuum is then pulled on the flask until the vacuum reached about 100 Pa while maintaining the temperature of the copolymer solution at 18±1° C. The distilled solution is collected in a cold trap and monitored by GC-MS until no unreacted monomers, including 1234ze and ethyl vinyl ether, or solvent were detected. The vacuum pump, agitation and temperature control is discontinued. Then ZnO was removed off by filtration. A transparent and colorless copolymer solution was obtained. After that, added Al2O3 molecular sieve A202-HF, a UOP product (8.0 wt % of the total polymer weight) or molecular sieve P188, a UOP product (2.0 wt % of the total polymer weight)) or Al2O3 powder (7% wt) were added into the clear copolymer solution and the solution is heated to 87±2° C. for 14-18 hours with 250 rpm agitation. Agitation is then stopped, the glass flask is cooled to room temperature, the Al2O3 molecular sieve was removed off by filtration, a clear solution was obtained. The solution was then diluted to 0.1%-10% solid content by butyl acetate. Then the solution is coated and cured.

### Example 3—Fluoropolymer Preparation

A solution polymerization operation is carried out by charging into a 300 ml stainless steel autoclave equipped with a stirrer the components as indicated in the following Table 3A:

TABLE 3A

| | | | | Mono- | Mono- |
|---|---|---|---|---|---|
| COMPONENT | | Weight, | | mer | mer, |
| TYPE | NAME | grams | Wt % | Moles | mol % |
| Solvent | butyl acetate | 120 | 66 | | |
| First Monomer | trans-1,3,3,3- | 19.6 | 5.1 | 0.17 | 25.32 |
| (fluoropolymer) | tetrafluoro- | | | | |
| | propene | | | | |
| | (transHFO- | | | | |
| | 1234ze) | | | | |
| Second Monomer | CTFE | 19.9 | 5.2 | 0.17 | 25.32 |
| Third Monomer | VEOVA-10 | 23.63 | 13 | 0.12 | 17.58 |
| (vinyl ester) | | | | | |
| Third Monomer | ethyl vinyl | 8.6 | 4.7 | 0.12 | 18.09 |
| (ethyl vinyl ether) | ether | | | | |
| Fourth Monomer | hydroxybutyl- | 10.83 | 6 | 0.19 | 13.75 |
| (alkylhydroxy | vinyl ether | | | | |
| ether) | | | | | |
| Initiator | tertbutyl- | 0.2 | 0.1 | | |
| | peroxypivalate | | | | |

The toluene, the ethyl vinyl ether monomer, the vinyl ester monomer (VEOVA-10), the hydroxybutyl vinyl ether, the initiator and 2 grams of zinc oxide were charged into the vessel. The mixture was solidified with liquid nitrogen, and deaerated to remove the dissolved air. Then the trans1,3,3,3-tetrafluoropropene (transHFO-1234ze) and CTFE was added to the mixture in the autoclave, and the mixture was then gradually heated to about 75° C. The mixture was then stirred for about 4 hours to carry-out solution copolymerization of the monomers. After the autoclave was cooled to room temperature, any unreacted monomers were purged and then the autoclave was opened and a vacuum was applied to the autoclave for a sufficient period of time to remove sufficient excess solvent to achieve a solid content (copolymer content) in the autoclave of about 50-80% by weight. The final fluorocopolymer (without solvent) was tested and found to have: a number average molecular weight (Mn) of about 18000 and a Mw/Mn of 3.2; a hydroxyl value of 72 mg KOH/g; a Fluorine content of 16% and a Chlorine content of 15%. The resulting copolymer plus solvent combination was in the form of a clear solution having a solid, that is, copolymer, content of about 70% and a VOC content of about 400 g/l.

The solvent/polymer resulting from the operation described above is then added to each of the materials identified in Table 3B below on a 1:1 weight basis and is found to form a clear solution at room temperature:

TABLE 3B
(b) - Solubility Test (1:1 wt ratio)

| Solvent | Appearance |
|---|---|
| Methanol | Clear solution |
| Ethanol | Clear solution |
| Petroleum Ether | Clear solution |
| n-Hexane | Clear solution |
| Xylene | Clear solution |
| Toluene | Clear solution |
| Methyl Ethyl Ketone | Clear solution |
| Acetone | Clear solution |
| Propylene Glycol | Clear solution |
| Monomethyl Ether | |
| [symbol] | |
| Butyl Acetate | Clear solution |
| THE | Clear solution |

[symbol]

indicates data missing or illegible when filed

The result reported above indicates that the fluorocopolymer according to the present invention is capable of forming solutions with many materials that may be used in or form a substantial part of formulations for protective coatings, and accordingly the present fluorocopolymer has excellent usefulness in the formation of protective coatings in conjunction with a wide variety of materials that may be used, for example, as supplemental carriers in such coating compositions.

### Example 4—Coating Composition and Coating Properties

A coating composition in the form of a white paste is formed by adding butyl acetate as thinner into copolymer solution formed in Example 3 to obtain a solution with a solid content of about 30-40 wt %. This solution is then charged into a glass flask and agitated at 250 rpm. A vacuum is then pulled on the flask until the vacuum reached about 100 Pa while maintaining the temperature of the copolymer solution at 18±1° C. The distilled solution is collected in a cold trap and monitored by GC-MS until no unreacted monomers, including 1234ze and ethyl vinyl ether, or solvent were detected. The vacuum pump, agitation and temperature control is discontinued. Then ZnO was removed off by filtration. A transparent and colorless copolymer solution was obtained.

After that, added Al2O3 molecular sieve A202-HF, a UOP product (8.0 wt % of the total polymer weight) or molecular sieve P188, a UOP product (2.0 wt % of the total polymer weight)) or Al2O3 powder (7% wt) were added into the clear copolymer solution and the solution is heated to 87±2° C. for 14-18 hours with 250 rpm agitation. Agitation is then stopped, the glass flask is cooled to room temperature, the Al2O3 molecular sieve was removed off by filtration, a clear solution was obtained. The solution was then diluted to 0.1%-10% solid content by butyl acetate. Then the solution is coated and cured.

### Example 5A—Coated LED Package

An LED package is assembled in accordance with the procedures described in FIGS. 3A-3C using the coating composition as described in Example 2. An LED package with improved performance properties is formed.

### Example 5B—Coated LED Package

An LED package is assembled in accordance with the procedures described in FIGS. 3A-3C using the coating composition as described in Example 4. An LED package with improved performance properties is formed.

### Example 6A—Coated LED Package

An LED package is assembled in accordance with the procedures described in FIGS. 3A and 3D using the coating composition as described in Example 2. An LED package with improved performance properties is formed.

### Example 6B—Coated LED Package

An LED package is assembled in accordance with the procedures described in Figures FIGS. 3A and 3D using the coating composition as described in Example 4. An LED package with improved performance properties is formed.

### Example 7A—Coated LED Package

An LED package is assembled in accordance with the procedures described in FIGS. 3A and 3E using the coating composition as described in Example 2. An LED package with improved performance properties is formed.

### Example 7B—Coated LED Package

An LED package is assembled in accordance with the procedures described in Figures FIGS. 3A and 3E using the coating composition as described in Example 4. An LED package with improved performance properties is formed.

### Example 8A—Coated LED Package

An LED package is assembled in accordance with the procedures described in FIGS. 3A and 3F using the coating composition as described in Example 2. An LED package with improved performance properties is formed.

### Example 8B—Coated LED Package

An LED package is assembled in accordance with the procedures described in Figures FIGS. 3A and 3F using the coating composition as described in Example 4. An LED package with improved performance properties is formed.

### Examples 9A-9C—Cross-Linkable Coating Preparation

The materials identified in Table 9 below are mixed together to form a cross-linkable coating composition:

| | Wt % | | |
|---|---|---|---|
| Component | Ex 9A, | Ex 9B | Ex 9C |
| Fluorocopolymer | | | |
| P283 (73% by | 4.17 | | |
| weight of | | | |
| copolymer in | | | |
| butyl acetate) | | | |
| JF-2X (57% by | | 4.34 | |
| weight of | | | |
| copolymer in | | | |
| xylene) | | | |
| GK570 (65% by | | | 4.78 |
| weight of | | | |
| copolymer in | | | |
| butyl acetate) | | | |
| Butyl Acetate | 62.53 | 65.16 | 72.12 |
| Cross-Linking | | | |
| Agent | | | |
| Isocyanate | 0.78 | 0.3 | 0.73 |
| (N3390) | | | |
| Butyl Acetate | 32.52 | 30.2 | 22.46 |

P283 is a tetracopolymer in butyl acetate, where the copolymer is made in accordance with the present invention made from the following combination and amount of monomers: about 50 mole % transHFO-1234ze, about 10-20 mole % of vinyl ester monomer (VEOVA-10); about 10-20 mole % ethyl vinyl ether; and about 3 to about 30 mole % hydroxybutyl vinyl ether, having a OH value 25 and a molecular weight of 10,000-15,000.
JF-2X is a copolymer in xylene, where the copolymer is a CTFE/vinyl ester and/or vinyl ether copolymer provided by 3F, and having OH value 25 and a molecular weight of 13,000-15,000.
GK-570 is a copolymer in butyl acetate, where the copolymer is a tetrafluorethylene (TFE) copolymer copolymerized with at least one hydroxyl-containing vinyl comonomers and does not contain CTFE and having an OH value of 55-65.

### Example 10—Coated LED Package

An LED package is assembled in accordance with the procedures described in FIGS. 3A-3C, using the coating composition as described in Example 9A between the chip and the encapsulant. The coating is then heated to a temperature of about 80C for about 24 hours to achieve crosslinking, which results in a cross-linked coating consisting essentially of solid copolymer. An LED package with improved performance properties is formed.

### Example 11—Coated LED Package

An LED package is assembled in accordance with the procedures described in FIGS. 3A-3C, using the coating composition as described in Example 9B between the chip and the encapsulant. The coating is then heated to a temperature of about 80C for about 24 hours to achieve crosslinking, which results in a cross-linked coating consisting essentially of solid copolymer. An LED package with improved performance properties is formed.

### Example 12—Coated LED Package

An LED package is assembled in accordance with the procedures described in FIGS. 3A-3C, using the coating composition as described in Example 9CB between the chip and the encapsulant. The coating is then heated to a temperature of about 80C for about 24 hours to achieve crosslinking, which results in a cross-linked coating consisting essentially of solid copolymer. An LED package with improved performance properties is formed.

What is claimed is:

1. A method of forming LEDs and LED packages having improved resistance to infiltration by chemical entities comprising:
(a) providing at least a portion of an LED chip or an LED chip package;
(b) providing a coating composition comprising:
(1) one or more hydrofluoroolefin monomer(s) selected from the group consisting of tetrafluoroethylene, hydrofluoroethylenes, hydrofluoropropenes, hydrofluorobutenes, hydrofluoropentenes and combinations of these;
(2) optionally one or more chlorofluoroethylene monomers;
(3) optionally one or more vinyl ester monomer(s); and
(4) optionally one or more vinyl ether monomer(s), wherein at least a portion of said vinyl ether monomer is a hydroxyl group-containing vinyl ether monomer.
(c) coating at least a portion of said LED chip or said LED chip package with said provided coating, preferably by a wet process; and
(d) curing said coating to provide a protective coating on said at least a portion of said LED chip or LED chip package.

2. The method of claim 1 wherein said one or more hydrofluoroolefin monomer(s) is selected from tetrafluoroethylene, 2,3,3,3-tetrafluoropropene, 1,3,3,3-tetrafluoropropene, and combinations of these.

3. The method of claim 1 wherein said one or more hydrofluoroolefin monomer(s) comprises 1,3,3,3-tetrafluoropropene.

4. The method of claim 1 wherein said one or more hydrofluoroolefin monomer(s) consists essentially of trans-1,3,3,3-tetrafluoropropene,

5. The method of claim 1 wherein said one or more hydrofluoroolefin monomer(s) consists of trans-1,3,3,3-tetrafluoropropene.

6. The method of claim 1 wherein said provided coating composition of step (b) comprises one or more of said chlorofluoroethylene monomers, one or more of said vinyl ester monomer(s), one or more vinyl ether monomer(s).

7. The method of claim 6 wherein said vinyl ether monomer comprises at least one hydroxyl group-containing vinyl ether monomer.

8. The method of claim 1 wherein said one or more chlorofluoroethylene monomers is present in said provided coating composition of step (b) and comprises chlorotrifluoroethylene (“CTFE”) monomer.

9. The method of claim 7 wherein said one or more chlorofluoroethylene monomers is present in said provided coating composition of step (b) and consists essentially of chlorotrifluoroethylene (“CTFE”) monomer.

10. The method of claim 1 wherein said coating step (c) comprises a wet process.

11. An LED or LED package with improved resistance to infiltration by chemical entities comprising a protective coating on at least a portion or component of said LED chip or said LED chip package, said coating comprising a polymer formed by copolymerization of:
(a) one or more hydrofluoroolefin monomer(s) selected from the group consisting of tetrafluoroethylene, hydrofluoroethylenes, hydrofluoropropenes, hydrofluorobutenes, hydrofluoropentenes and combinations of these and combinations of these;
(b) optionally one or more chlorofluoroethylene monomers;
(c) optionally one or more vinyl ester monomer(s); and
(d) optionally one or more vinyl ether monomer(s), provided that at least one of monomers (b) or (d) are included.

12. The LED or LED package of claim 11 wherein said one or more hydrofluoroolefin monomer(s) is selected from tetrafluoroethylene, 2,3,3,3-tetrafluoropropene, 1,3,3,3-tetrafluoropropene, and combinations of these.

13. The LED or LED package of claim 11 wherein said one or more hydrofluoroolefin monomer(s) consists essentially of trans-1,3,3,3-tetrafluoropropene,

14. The LED or LED package of claim 11 wherein said polymer is formed by copolymerization that includes one or more of said chlorofluoroethylene monomers, one or more of said vinyl ester monomer(s), one or more of said vinyl ether monomer(s).

15. The LED or LED package of claim 14 wherein said vinyl ether monomer comprises at least one hydroxyl group-containing vinyl ether monomer.

16. The LED or LED package of claim 14 wherein said one or more chlorofluoroethylene monomers is used in polymerization and comprises chlorotrifluoroethylene (“CTFE”) monomer.

17. A method for forming a protected LED chip package comprising:
(a) providing a coating composition formed by steps comprising:
(i) providing one or more fluoropolymers by copolymerization of (1) one or more fluoroolefins, (2) one or more vinyl ester monomer(s), and (3) one or more vinyl ether monomer(s), wherein at least a portion of said vinyl ether monomer is a hydroxyl group-containing vinyl ether monomer; and
(ii) providing curing agent and
(iii) providing carrier for said one or more fluoropolymers and said curing agent; and
(b) combining said one or more fluoropolymers with said curing agent and said carrier,
(c) applying to at least a portion of the LED and/or the LED package or any component thereof said coating composition; and
(d) forming a protective polymeric layer on said LED and/or the LED package or any component thereof by removing at least a substantial portion of said carrier and by crosslinking using said crosslinking agent.

18. The method of claim 17 wherein said evaporating and said crosslinking preferably comprises heating said coating after said step (c).

19. The method of claim 17 wherein said hydrofluoroolefin monomer(s) is selected from the group consisting of tetrafluoroethylene, CTFE, hydrofluoroethylenes, hydrofluoropropenes, hydrofluorobutenes, hydrofluoropentenes and combinations of these, and preferably selected from tetrafluoroethylene, CTFE, 2,3,3,3-tetrafluoropropene, 1,3,3,3-tetrafluoropropene.

20. The method of claim 17 wherein said hydrofluoroolefin monomer(s) comprises 1,3,3,3-tetrafluoropropene and wherein said 1,3,3,3-tetrafluoropropene consisting essentially of or consisting of trans-1,3,3,3-tetrafluoropropene.

21. The method of claim 17 wherein said curing agent comprises an isocyanate and/or an amine curing agent.
